(19) United States
(12) Patent Application Publication
(10) Pub. No.: US 2026/0115636 A1
(43) Pub. Date: Apr. 30, 2026

(54) METHOD AND SYSTEM FOR RESIST DEFECT REDUCTION

(71) Applicant: TAIWAN SEMICONDUCTOR MANUFACTURING COMPANY, LTD., Hsinchu (TW)

(72) Inventors: Yen-Yu KUO, New Taipei City (TW); Yu-Chung SU, Hsinchu City (TW); Ching-Yu CHANG, Yilang County (TW)

(73) Assignee: TAIWAN SEMICONDUCTOR MANUFACTURING COMPANY, LTD., Hsinchu (TW)

(21) Appl. No.: 18/933,626

(22) Filed: Oct. 31, 2024

(51) Int. Cl. B01D 37/04; B01D 29/56; B01D 36/00; G03F 7/16

(52) U.S. Cl. CPC B01D 37/045; B01D 29/56; B01D 36/00; G03F 7/168

(57) ABSTRACT

A method includes following steps. A resist liquid is flowed into a first tank and a filtration process is performed to the resist liquid. The filtration process comprises one or more repetitions of a cyclic process. The cyclic process comprises following steps. The first step of cyclic process is pumping the resist liquid from the first tank to a second tank through a first filter in a first pipeline. The second step of cyclic process is determining whether a liquid level in the first tank drops below a first predetermined threshold. The third step of cyclic process is in response to determining that the liquid level in the first tank drops below the first predetermined threshold, pumping the resist liquid from the second tank back to the first tank.

### BACKGROUND

Lithography is used for patterning the surface of a wafer that is covered by a resist liquid. The resist liquid is patterned so that portions of the resist liquid can be selectively removed to expose underlying areas of the wafer for selective processing such as etching, material deposition, implantation and the like. Photolithography utilizes light energy beams, including ultraviolet light or X-ray, for selective exposure of the resist liquid. Alternatively, charged particle beams, e.g., electron beams and ion beams, have been used for high resolution lithographic resist exposure.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow chart illustrating an exemplary process for generating a layout pattern in a resist layer on a wafer, in accordance with some embodiments of the present disclosure.

FIG. 2 is a schematic side view of a lithography tool, in accordance with some embodiments of the present disclosure.

FIG. 3 illustrates a schematic diagram of a resist filtration system in accordance with some embodiments of the present disclosure.

FIG. 4 is a flow chart illustrating an exemplary resist filtration process in accordance with some embodiments of the present disclosure.

FIGS. 5A-5C are schematic diagrams illustrating intermediate stages in the resist filtration process of FIG. 4.

FIG. 6A is a graph illustrating experimental results showing the throughput improvement of a multi-tank filtration process compared to a single-tank circulation filtration process over various filtration durations.

FIG. 6B is a graph illustrating experimental results showing the throughput improvement of a multi-tank filtration process compared to a single-tank circulation filtration process over various filter efficiencies.

FIG. 7 is a flow chart illustrating another exemplary resist filtration process in accordance with some embodiments of the present disclosure.

FIGS. 8A-8C are schematic diagrams illustrating intermediate stages in the resist filtration process of FIG. 7.

FIG. 9 illustrates a schematic diagram of a resist filtration system in accordance with some embodiments of the present disclosure.

FIG. 10 is a flow chart illustrating another exemplary process for generating a layout pattern in a resist layer on a wafer, in accordance with some embodiments of the present disclosure.

FIG. 11 is a schematic side view of a lithography tool, in accordance with some embodiments of the present disclosure.

FIG. 12 illustrates a schematic diagram of a resist dispense/filtration system in accordance with some embodiments of the present disclosure.

FIG. 13 is a flow chart illustrating an exemplary resist filtration process in accordance with some embodiments of the present disclosure.

FIGS. 14A-14C are schematic diagrams illustrating intermediate stages in the resist filtration process of FIG. 13.

FIG. 15 is a flow chart illustrating an exemplary resist filtration process in accordance with some embodiments of the present disclosure.

FIGS. 16A-16C are schematic diagrams illustrating intermediate stages in the resist filtration process of FIG. 15.

FIG. 17 illustrates a schematic diagram of a resist dispense/filtration system in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 230 degrees or at other orientations) and the spatially relative descriptors used herein may likewise be interpreted accordingly. As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced with the down-scaling of the integrated circuits.

During the design of an integrated circuit (IC), various layout patterns are generated for different stages of IC processing. These layout patterns consist of geometric shapes that correspond to structures to be fabricated on a wafer. The layout patterns may be patterns on a photomask that are projected, e.g., imaged, on a resist liquid on the wafer to create the IC. A lithography process transfers the photomask's pattern onto the resist liquid, enabling subsequent steps such as etching or implantation to be applied to specific regions of the wafer.

The layout pattern generated in resist layer dispensed on the surface of the wafer defines the critical dimensions (CD) of various features. An impurity or defect in the resist liquid may cause the resist liquid to not react accordingly and thus may generate CD non-uniformity in the layout pattern. Therefore, to maintain high device yield, it is helpful to minimize defects, such as foreign particles, in the resist liquid coated on the wafer. One method to achieve this is by employing a resist filtration system to remove defects from the resist liquid. An example resist filtration system includes a circulation loop with a single resist storage tank and a filter. In this setup, resist liquid is pumped from the storage tank through the filter and then immediately returned to the same tank using a circulation pipeline, maintaining a continuous flow within the circulation loop. However, this configuration may degrade the throughput of resist filtration system because the filtered resist liquid mixes with the unfiltered resist liquid as soon as it re-enters the storage tank.

To address this issue, the present disclosure, in various embodiments, introduces an improved resist filtration system that incorporates multiple tanks. Specifically, one or more buffer tanks are positioned downstream of the initial resist storage tank. The one or more buffer tanks temporarily store the filtered resist liquid, creating a discontinuity in the flow of resist liquid in the circulation loop. This discontinuity prevents filtered resist liquid from continuously mixing with the unfiltered resist liquid in the initial storage tank. Once the liquid level in the initial storage tank drops below a certain threshold (e.g., 30% of its initial level), the filtered resist liquid is pumped back into the initial storage tank. This approach significantly reduces the defect concentration in the mixed resist liquid compared to the single-tank filtration system within the same filtration process duration, thereby enhancing the overall efficiency of the resist filtration process.

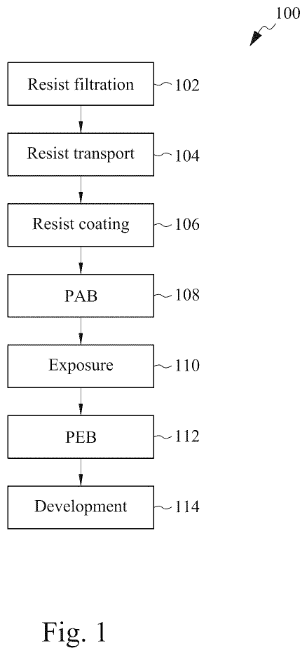

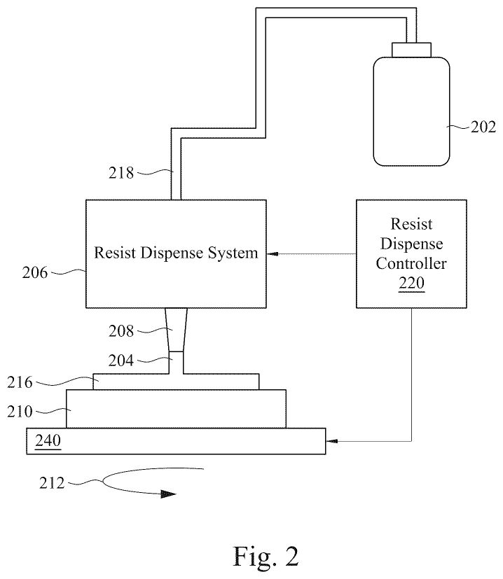

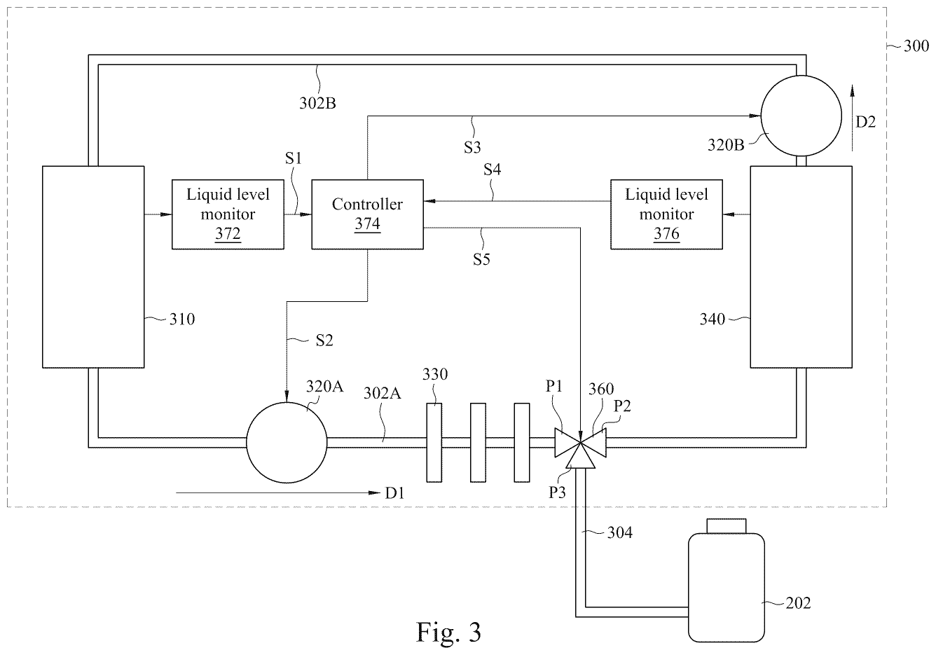

FIG. 1 is a flow chart illustrating an exemplary process 100 for generating a layout pattern in a resist layer on a wafer, in accordance with some embodiments of the present disclosure. In operation 102, an unfiltered resist liquid (i.e., raw resist liquid) is filtered in a multi-tank resist filtration system. The multi-tank resist filtration system and its operation are described in detail with respect to FIGS. 3-8C. In operation 104, the filtered resist liquid is transported to a lithography tool in a semiconductor fabrication facility (FAB), as illustrated in FIG. 2.

In operation 106, the filtered resist liquid is dispensed, e.g., coated, on a top surface of a substrate, e.g., a wafer or a work piece, to form a resist layer. Forming the resist layer on the top surface of the wafer is described with respect to FIG. 2. At operation 108, a post application bake (PAB) operation is performed. The wafer including the resist layer is baked to drive out solvent in the resist liquid and solidify the resist layer on top of the wafer. At operation 110, which is an exposure operation, the resist layer is irradiated with actinic radiation or a charged particle beam to project a mask pattern onto the resist layer. In some embodiments, a layout pattern on a mask is projected by a deep ultraviolet (DUV) radiation from a DUV light source or an extreme ultraviolet (EUV) radiation from an EUV light source onto the resist layer to generate the layout pattern in the resist layer on the wafer. In some embodiments, portions of the resist layer are exposed to an electron beam from an electron beam source to generate the layout pattern in the resist layer on the wafer.

At operation 112, a post exposure bake (PEB) operation 112 is performed on the wafer and at operation 114, by applying a developer solution, the resist liquid of the resist layer is developed. For a positive tone resist liquid, the exposed regions are developed by applying a developer solution and then are removed and the layout pattern is generated in the resist layer. For a negative tone resist liquid, the non-exposed regions are developed by applying the developer solution and are subsequently removed and the layout pattern is generated in the resist layer.

FIG. 2 is a schematic cross-sectional view of a resist dispensing tool, illustrating an operation for dispensing a resist layer 216 on a surface of a wafer. A resist liquid 204, e.g., a photoresist liquid, is coated on a surface of a substrate 210, e.g., a wafer, to form the resist layer 216 of FIG. 2. The resist liquid 204 is dispensed from a resist dispensing nozzle 208, which is an outlet of a resist dispense system 206. In some embodiments, a resist dispense controller 220 is coupled to a resist dispense system 206 to control a thickness of the resist layer 216 that is produced on the substrate 210. The resist dispense system 206 is fluidly coupled to a resist container 202 (e.g., a resist bottle) and the resist dispensing nozzle 208, and transfers the resist liquid from the resist container 202, via a pipeline 218 (e.g., one or more pipes, conduits, or tubes), to the resist dispensing nozzle 208. In some embodiments, the substrate 210 is placed on a stage 240 and the stage 240 rotates around a rotation direction 212 to uniformly distribute the resist liquid on the substrate 210. In some embodiments, a protection segment (not shown) is coated in an edge region around an edge of the substrate 210 to prevent the resist liquid from spilling over the edge of the substrate 210. In some embodiments, the resist dispense controller 220 is also coupled to a stage controller (not shown) in the stage 240 to synchronize the dispensing of the resist liquid and the rotation of the substrate 210. In some embodiments, the substrate 210 is used for manufacturing semiconductor devices (e.g., transistors) and, thus, includes one or more layers of the semiconductor devices below the resist layer 216. In some embodiments, the stage 240 rotates around a direction opposite to the rotation direction 212.

In some embodiments, the resist layer 216 is a photosensitive layer that can be patterned by exposure to actinic radiation. In some embodiments, the resist layer 216 is sensitive to charged particles and the resist layer 216 can be patterned by exposure to a charged particle beam, e.g., an electron beam. The chemical properties of the resist regions struck by actinic radiation or the charged particle beam may change in a manner that depends on the type of resist used. The resist layer 216 is either a positive tone resist or a negative tone resist. A positive tone resist refers to a resist liquid that when exposed to the charged particle beam or the actinic radiation (UV light, e.g., EUV) becomes soluble in a developer, while the region of the resist that is non-exposed (or exposed less) is insoluble in the developer, leaving behind a coating in areas that were not exposed. A negative tone resist, on the other hand, refers to a resist liquid that when exposed to the charged particle beam or the actinic radiation becomes insoluble in the developer, while the region of the resist that is non-exposed (or exposed less) is soluble in the developer. The region of a negative resist that becomes insoluble upon exposure to radiation may become insoluble due to a cross-linking reaction caused by the exposure to radiation, leaving behind a coating in areas that were exposed.

In some embodiments, the resist liquid 204 in the resist container 202 has already been filtered before it is packaged into the resist container 202. In some embodiments, the resist filtration process may be performed in a stand-alone facility operated by the photoresist vendor, which is independent of the resist dispensing tool as illustrated in FIG. 2. FIG. 3 illustrates a diagram of a resist filtration system 300 in accordance with some embodiments of the present disclosure. The resist filtration system 300 includes a circulation loop comprising a storage tank 310, one or more filters 330 downstream of the storage tank 310, one or more buffer tanks 340 downstream of the one or more filters 330, a first pipeline 302A downstream of the storage tank 310 and upstream of the buffer tank 340 and fluidly connecting the storage tank 310 to the buffer tank 340, a second pipeline 302B downstream of the buffer tank 340 and upstream of the storage tank 310 and fluidly connecting the buffer tank 340 to the storage tank 310, a first pump 320A fluidly connected to the first pipeline 302A, and a second pump 320B fluid connected to the second pipeline 302B.

The first pump 320A can initiate and drive a flow of resist liquid through the first pipeline 302A, enabling the resist liquid to flow from the storage tank 310 to the buffer tank 340 via one or more filters 330. The second pump 320B can initiate and drive a flow of resist liquid through the second pipeline 302B, enabling the resist liquid to return from the buffer tank 340 back to the storage tank 310. Together, the first pipeline 302A and the second pipeline 302B enable the circulation of the resist liquid within the loop.

As the unfiltered resist liquid flows through one or more filters 330 in the first pipeline 302A, the filters 330 remove defects such as particles, thereby reducing the defect concentration in the resist liquid. Once filtered, the filtered resist liquid flows into the buffer tank 340, where it can be temporarily stored instead of immediately returning to the storage tank 310. For instance, when the first pump 320A is activated (i.e., turned on), it drives the resist liquid to flow through the filters 330 and into the buffer tank 340. During this time, the second pump 320B remains deactivated (i.e., turned off), allowing the filtered resist liquid to stay in the buffer tank 340. Once the first pump 320A has sufficiently lowered the liquid level in the storage tank 310 below a predetermined threshold (e.g., 30% of its initial liquid level), the second pump 320B is activated. This activation initiates the flow of filtered resist liquid from the buffer tank 340 back to the storage tank 310, where it mixes with the unfiltered resist liquid.

Compared to a single-tank filtration system, where the filtered resist liquid continuously mixes with the unfiltered resist liquid throughout the entire filtration process, the multi-tank filtration system can significantly reduce the defect concentration in the mixed resist liquid within the same filtration process duration, thereby enhancing the overall efficiency of the resist filtration process. This enhanced efficiency is achieved because, in a single-tank system, the defect concentration in the mixed resist liquid decreases slowly due to the filtered resist liquid continuously mixing with the unfiltered resist liquid. However, in the multi-tank system as illustrated in FIG. 3, the filtered resist liquid is mixed with the unfiltered resist liquid after the liquid level in the storage tank 310 has been sufficiently lowered, and thus the defect concentration in the mixed resist liquid drops sharply.

In some embodiments, the resist filtration system 300 includes a liquid level monitor 372 that is either connected to or integrated within the storage tank 310, and a liquid level monitor 376 that is either connected to or integrated within the buffer tank 340. This liquid level monitor 372 continuously tracks the liquid level in the storage tank 310 during the filtration process, generating real-time liquid level signals S1 based on the monitored data. These real-time signals S1 are then transmitted to a controller 374, which is in communication with the liquid level monitor 372. Similarly, the liquid level monitor 376 continuously tracks the liquid level in the buffer tank 340 during the filtration process, generating real-time liquid level signals S4 based on the monitored data. These real-time signals S4 are then transmitted to the controller 374, which is also in communication with the liquid level monitor 376. The controller 374 processes the real-time liquid level signals S1 and/or S4, and generates corresponding control signals S2 and S3, such as control voltages, based on the real-time liquid level signals S1 and/or S4. These control signals S2 and S3 are used to manage the operation of the pumps 320A and 320B. For example, the control signals S2 are sent to the first pump 320A to regulate its activation or deactivation, and the control signals S3 are sent to the second pump 320B to regulate its activation or deactivation.

In some embodiments, each of the liquid level monitors 372 and 376 may include a capacitive level sensor, an ultrasonic level sensor, optical sensor, pressure transducer, or a float switch, among other types of liquid level sensors. These sensors ensure accurate and reliable monitoring of the liquid level within the storage tank 310, facilitating efficient and automated control of the filtration process. In some embodiments, the controller 374 may include various types of controllers, such as, for example, a programmable logic controller (PLC), a microcontroller, a digital signal processor (DSP), or the like.

In some embodiments, the resist filtration system 300 further includes a valve 360 that regulates whether the resist liquid remains within the circulation loop or exits the loop through an outlet pipeline 304 for the next stage, such as being sealed in a resist container 202. In some embodiments, the valve 360 is a three-way valve, which offers enhanced control over the flow direction of the resist liquid. For example, the three-way valve 360 operates by providing three ports, which include an inlet port P1 and two outlet ports P2 and P3. The inlet port P1 of the three-way valve 360 receives the resist liquid from the last one of filters 330 in the circulation loop. The first outlet port P2 of the three-way valve 360 directs the resist liquid back into the circulation loop to the buffer tank 340. The second outlet port P3 of the three-way valve 360 allows the resist liquid to exit the circulation loop through the outlet pipeline 304 to the next stage, such as being transferred into a resist container 202 for storage.

In some embodiments, the controller 374 can manage the operation of the three-way valve 360 by sending control signals S5, such as control voltages, to switch the open/closed position of each port of the three-way valve 360. When the controller 374 determines that the resist liquid remains in the circulation loop for continuing the filtration process, the control signal S5 controls the three-way valve 360 to maintain an open position on the first outlet port P2 and a closed position on the second outlet port P3, thereby regulating the resist liquid to stay in the circulation loop. Conversely, when the controller 374 determines that the filtration process is completed and the resist liquid can be moved to the next stage, the controller 374 sends a control signal S5 to switch the three-way valve 360 to have a closed position on the first outlet port P2 and an open position on the second outlet port P3, allowing the resist liquid to flow out of the circulation loop and into the resist container 202.

In some embodiments, the first pump 320A is an in-line pump disposed within the first pipeline 302A. In some embodiments, the first pump 320A is a centrifugal pump allowing the resist liquid to flow straight through the pump 320A along a first direction D1 without significant changes in direction. In some embodiments, the second pump 320B is an in-line pump disposed within the first pipeline 302B. In some embodiments, the second pump 320B is a centrifugal pump allowing the resist liquid to flow straight through the pump 320B along a second direction D2 without significant changes in direction. The first and second directions D1 and D2 are the same direction in the circulation loop. For example, as illustrated in FIG. 3, the first and second directions D1 and D2 are both along a counterclockwise direction in the circulation loop. In some embodiments, the first pump 320A or the second pump 320B is a diaphragm pump, rotary pump, or a centrifugal pump which is control by a motor, a gear or an electromagnetic drive. In some embodiments, the first pump 320A and the second pump 320B are of different types of pump. In some embodiments, the first pump 320A and the second pump 320B are of the same type of pump.

In some embodiments, the first pump 320A and the second pump 320B operate asynchronously. For example, the first pump 320A and the second pump 320B are asynchronously activated by the controller 374. Specifically, the controller 374 activates the second pump 320B after the first pump 320A has been running for a sufficient duration. This allows that the filtered resist liquid remains in the buffer tank 340 until the first pump 320A has lowered the liquid level in the storage tank 310 below a predetermined threshold, such as 30% of its initial level. In some embodiments, the first pump 320A and the second pump 320B are asynchronously deactivated by the controller 374. For example, the controller 374 may activate and deactivate the second pump 320B after deactivating the first pump 320A. This prevents mixed resist liquid from being transferred from the storage tank 310 to the buffer tank 340 while the filtered resist liquid is being pumped back from the buffer tank 340 to the storage tank 310.

In some embodiments, one or more filters 330 are formed from materials such as nylon, high-density polyethylene (HDPE), perfluoroalkoxy alkane (PFA), or other types of polymers and materials that can be effectively used in photoresist particle filtration. For instance, nylon filters can be chosen for their excellent mechanical strength and chemical resistance, making them suitable for filtering out fine particles in resist liquid. HDPE filters, on the other hand, can be chosen for their high tensile strength and resistance to a wide range of chemicals. PFA filters can be chosen in environments requiring high thermal stability and resistance to aggressive chemicals, as they can withstand extreme conditions without degrading. Additionally, other materials such as polytetrafluoroethylene (PTFE) or polypropylene (PP) may also be employed as the materials of the filters 330 depending on targets of the filtration process, such as the size of the particles to be filtered, the chemical composition of the photoresist, and the operating temperature. In some embodiments, the filters 330 are formed of different materials.

In some embodiments, the storage tank 310 and/or the buffer tank 340 for the resist filtration are formed from materials such as PFA (perfluoroalkoxy alkane), PTFE (polytetrafluoroethylene), HDPE (high-density polyethylene), or glass. For instance, PFA can be chosen for its excellent chemical resistance and high purity, making it suitable for handling aggressive chemicals used in resist liquid. PTFE is another material with outstanding chemical resistance and non-stick properties, which can help in preventing contamination and promoting smooth flow of the resist liquid. HDPE is a durable and cost-effective option that provides good chemical resistance and mechanical strength, making it a practical choice for larger tanks. Glass offers high transparency, allowing for easy visual inspection of the resist liquid, and is resistant to a wide range of chemicals.

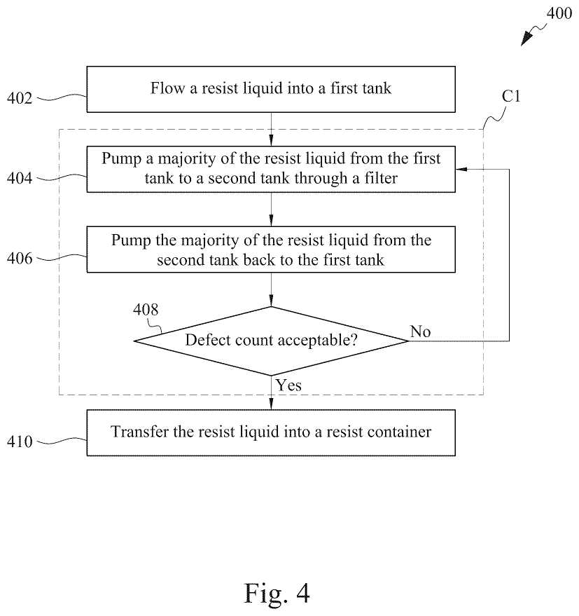

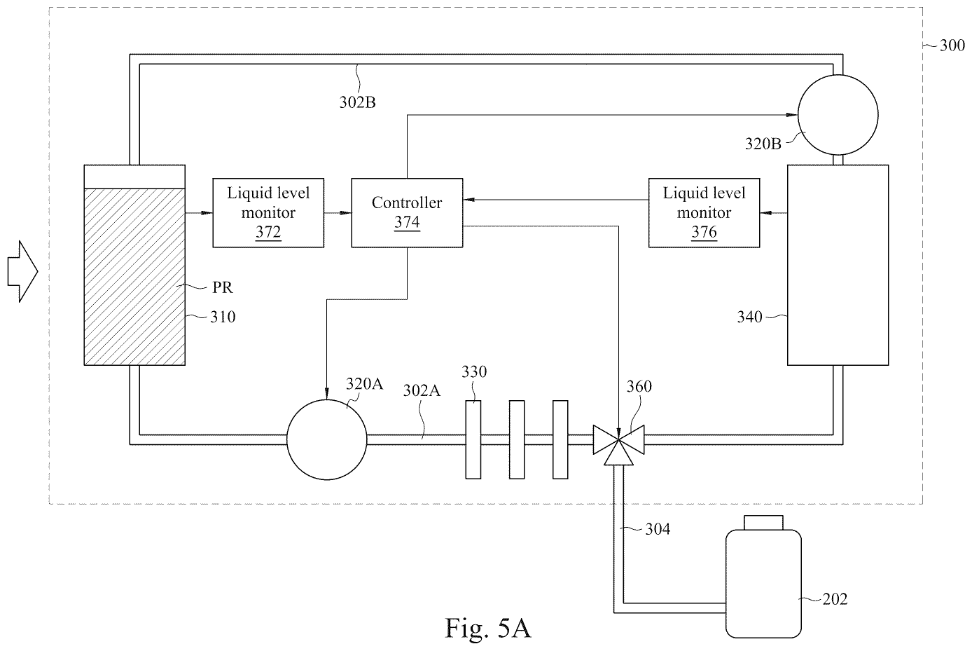

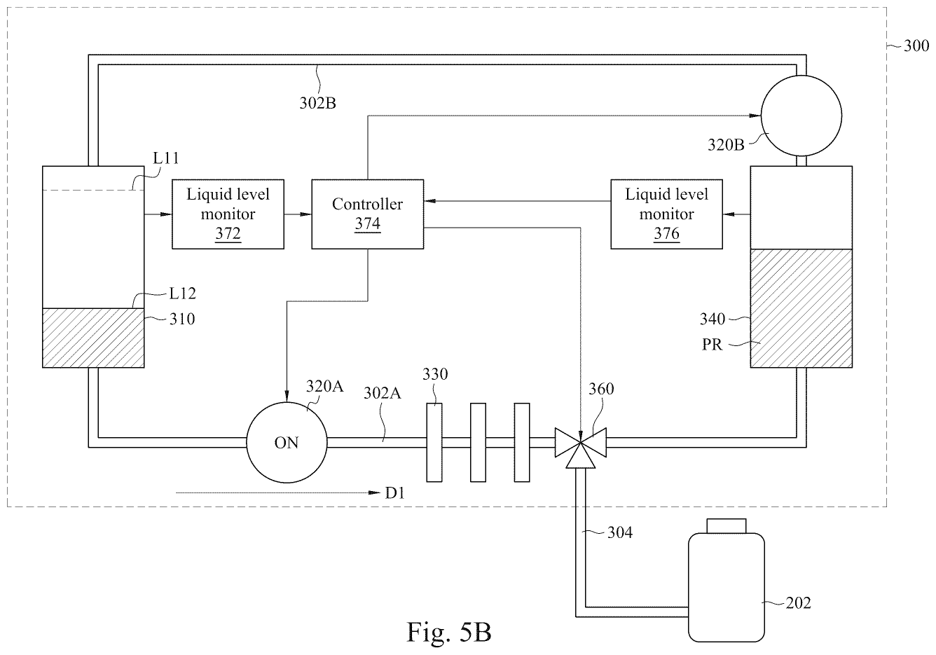

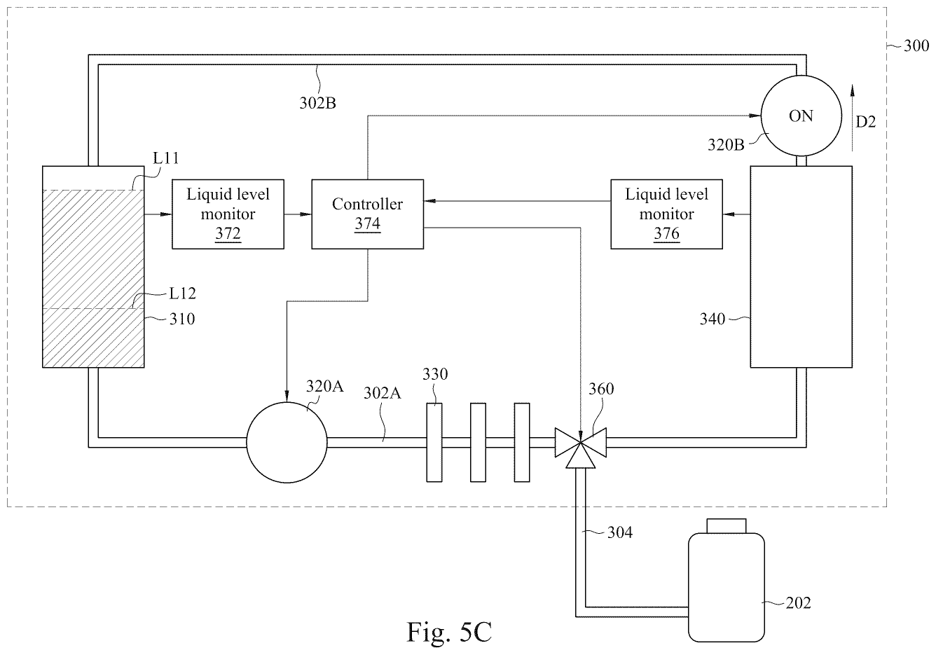

FIG. 4 is a flow chart illustrating an exemplary resist filtration process 400 in accordance with some embodiments of the present disclosure. In operation 402, a resist liquid flows into a first tank. FIG. 5A illustrates an example of operation 402, where a resist liquid PR, e.g., photoresist, flows into the storage tank 310 of the resist filtration system 300 manually or automatedly. In some embodiments, the resist liquid PR originates from a preceding stage in resist fabrication process. This previous stage may involve the synthesis of the resist liquid PR. During synthesis, various chemical components are combined under controlled conditions to produce the resist liquid PR.

In operation 404, a majority of the resist liquid is pumped from the first tank to a second tank through a filter. FIG. 5B illustrates an example of operation 404, where a majority of the resist liquid PR (e.g., more than 70% of the resist liquid PR) is pumped from the storage tank 310 to the buffer tank 340 through one or more filters 330 by the first pump 320A. During this step, the first pump 320A is activated, as indicated by the “ON” label in FIG. 5B, enabling the resist liquid PR to flow through the first pump 320A along the first direction D1 to the buffer tank 340, while the second pump 320B remains deactivated or in the “OFF” state. This ensures that the resist liquid PR is retained in the buffer tank 340, preventing it from immediately returning to the storage tank 310.

In operation 406, the majority of the resist liquid is pumped from the second tank back to the first tank to mix with the resist liquid in the first tank. FIG. 5C illustrates an example of operation 406, where an entirety of the filtered resist liquid PR in the buffer tank 340 is pumped from the buffer tank 340 back to the storage tank 310 by the second pump 320B to mix to the unfiltered resist liquid PR in storage tank 310. Stated differently, a volume of the resist liquid pumped from the buffer tank 340 back to the storage tank 310 is substantially equal to a volume of the resist liquid previously pumped from the storage tank 310 to the buffer tank 340. During this step, the second pump 320B is activated, as indicated by the “ON” label in FIG. 5C, enabling the resist liquid PR to flow through the second pump 320B along the second direction D2 to the storage tank 310, while the second pump 320A may remain deactivated or in the “OFF” state. This ensures that the mixed resist liquid PR is retained in the storage tank 310, preventing it from immediately flowing to the buffer tank 340.

In some embodiments, the operation 406 is initiated by the controller 374 when it determines that the liquid level in the storage tank 310 has dropped below a predetermined threshold. For example, when the real-time liquid level signals S1 generated by the liquid level monitor 372 indicates that the liquid level in the storage tank 310 has decreased from an initial level L11 to a level L12, which is less than, for example, 30% of the initial level L11, the controller 374 can activate the second pump 320B to pump the resist liquid PR from the buffer tank 340 back to the storage tank 310 in response to the real-time liquid level signals S1.

In operation 408, the mixed resist liquid is inspected to obtain a defect count in the mixed liquid. If the defect count is determined as unacceptable, then the resist filtration process 400 returns to perform the operations 404 and 406. The operations 404, 406, and 408 thus collectively form a cyclic process C1 that may repeat until in the latest operation 408 the defect count in the mixed resist liquid is acceptable, i.e., lower than a predetermined threshold. Once the defect count is determined as acceptable, in operation 410, the mixed resist liquid is transferred to a resist container. For example, when the defect count in the mixed resist liquid in the storage tank 310 is determined as acceptable, the controller 374 may switch the open/closed positions of outlet ports in the valve 360, enabling the mixed resist liquid in the storage tank 310 to exit the circulation loop to the resist container 202 through the outlet pipeline 304.

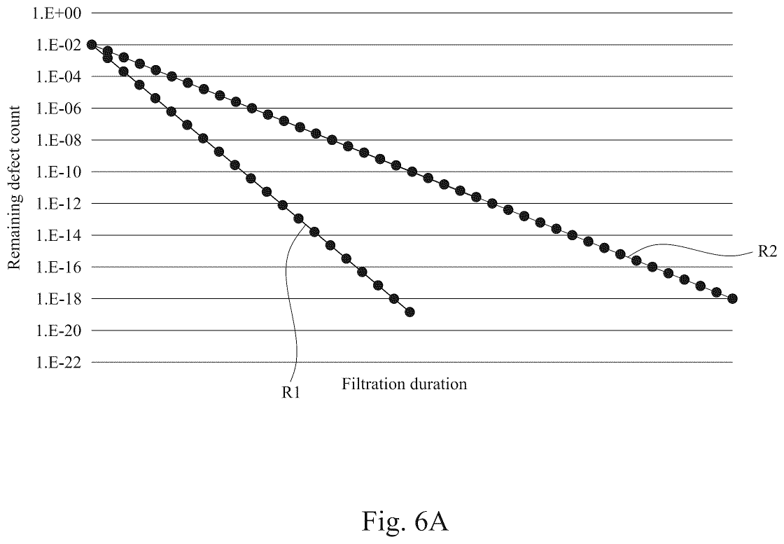

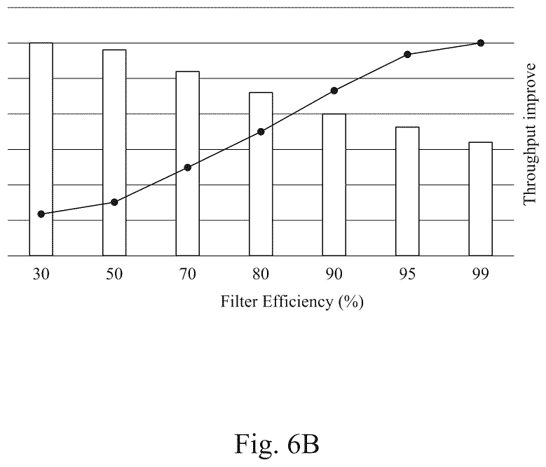

FIG. 6A is a graph illustrating experimental results showing the throughput improvement of a multi-tank filtration process compared to a single-tank circulation filtration process over various filtration durations. In FIG. 6A, the horizontal axis represents the duration of the filtration process, while the vertical axis indicates the remaining defect count. Line R1 depicts the remaining defect counts for the multi-tank filtration process at various durations, whereas line R2 shows the remaining defect counts for the single-tank filtration process over the same time periods. A comparative analysis of lines R1 and R2 reveals that the multi-tank filtration process consistently results in lower defect counts compared to the single-tank filtration process. Furthermore, this analysis further shows that the difference in remaining defect counts between the two processes increases as the filtration duration extends. These results indicate a significant improvement in the efficiency of the resist filtration process when employing the multi-tank approach.

FIG. 6B is a graph illustrating experimental results showing the throughput improvement of a multi-tank filtration process compared to a single-tank circulation filtration process over various filter efficiencies. In FIG. 6B, the horizontal axis represents the filter efficiency, and the vertical axis indicates the throughput improvement. Filter efficiency is defined as the ratio of the number of particles retained or trapped by the filter to the number of particles entering the filter, expressed as a percentage. Throughput improvement refers to the percentage increase in resist filtration throughput. Resist filtration throughput can be the total volume of resist liquid that can be filtered through the filtration system within a given time frame, reflecting the filtration system's capacity and efficiency. As illustrated in FIG. 6B, the experimental results show a clear trend, indicating throughput improvement increases as filter efficiency rises. This indicates that higher filter efficiency leads to a more significant enhancement in the resist filtration throughput, showing the improved performance of the multi-tank filtration process compared to the single-tank circulation filtration process.

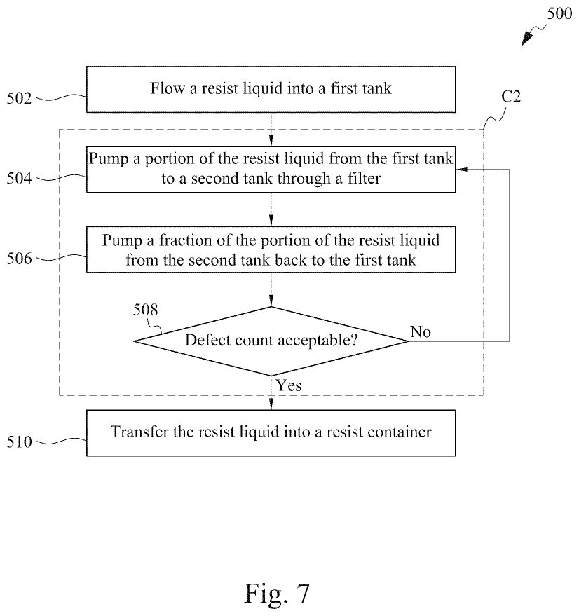

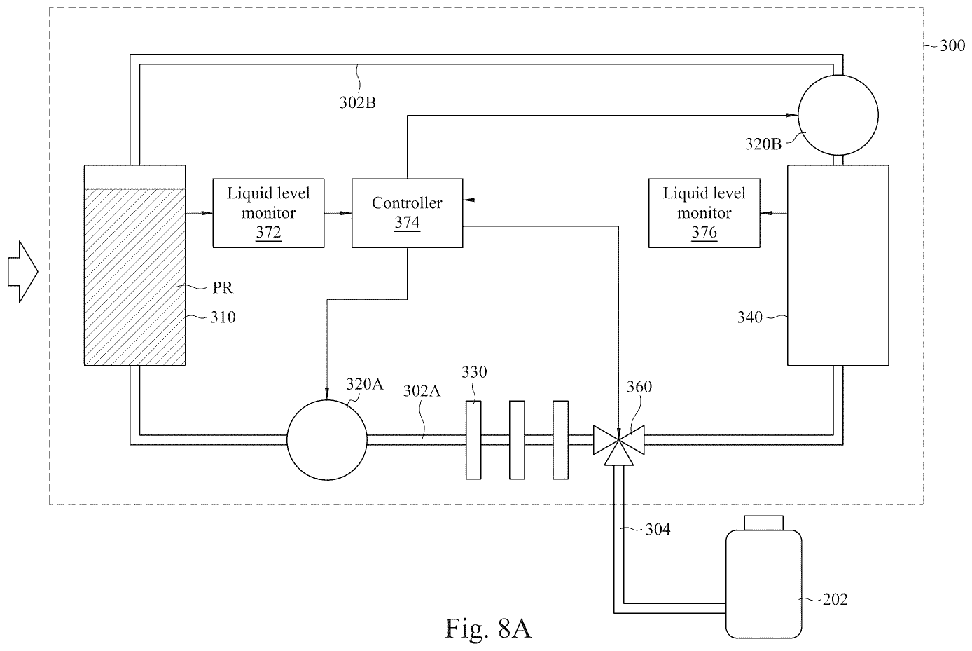

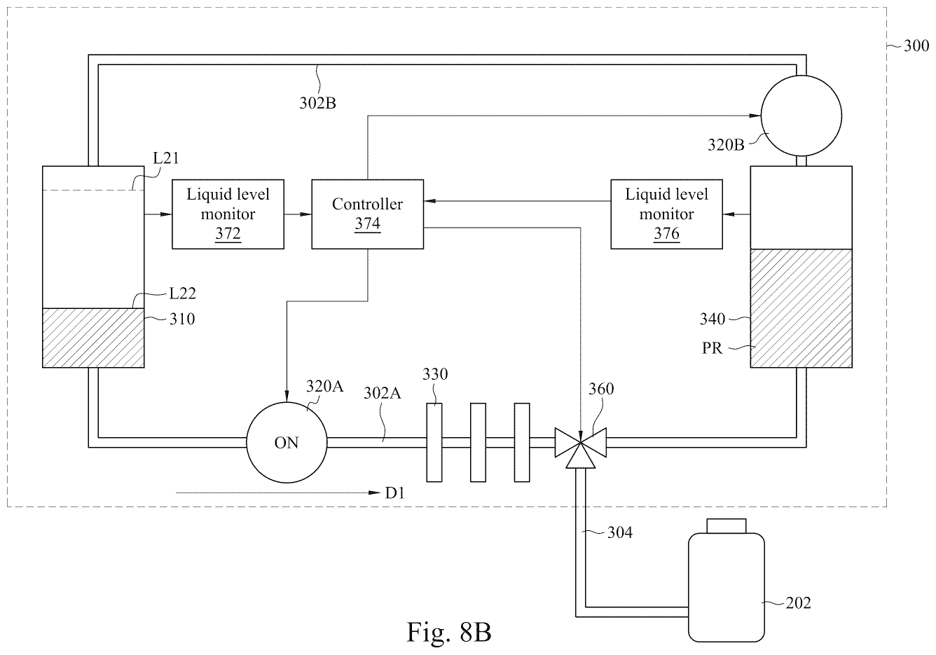

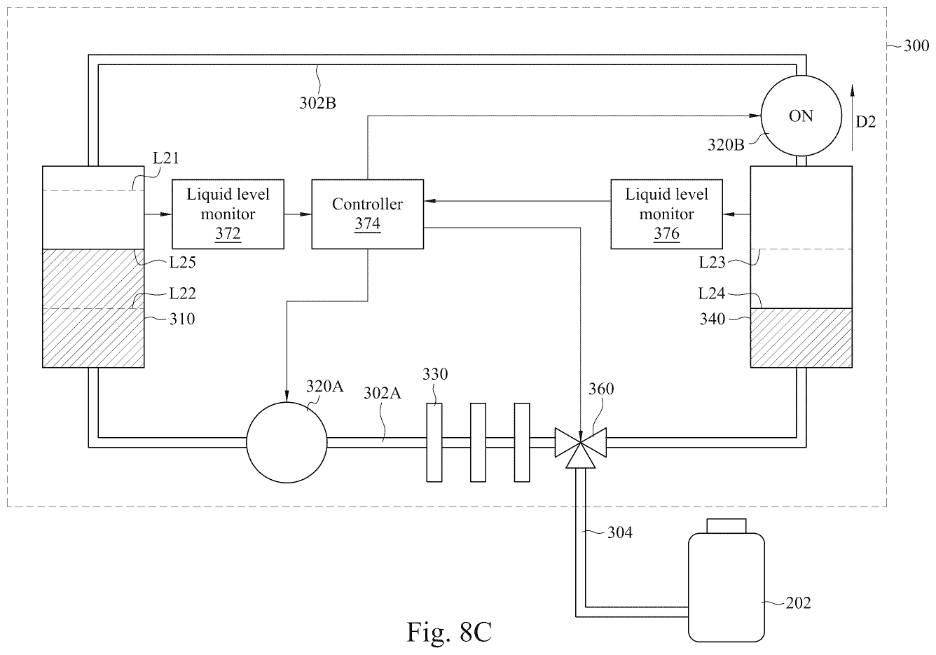

FIG. 7 is a flow chart illustrating another exemplary resist filtration process 500 in accordance with some embodiments of the present disclosure. In operation 502, a resist liquid flows into a first tank. FIG. 8A illustrates an example of operation 502, where a resist liquid PR, e.g., photoresist, flows into the storage tank 310 of the resist filtration system 300 manually or automatedly. In some embodiments, the resist liquid PR originates from a preceding stage in resist fabrication process. This previous stage may involve the synthesis of the resist liquid PR.

In operation 504, a portion of the resist liquid is pumped from the first tank to a second tank through a filter. FIG. 8B illustrates an example of operation 504, where a portion of the resist liquid PR (e.g., more than 70% of the resist liquid PR) is pumped from the storage tank 310 to the buffer tank 340 through one or more filters 330 by the first pump 320A. During this step, the first pump 320A is activated, as indicated by the “ON” label in FIG. 8B, enabling the resist liquid PR to flow through the first pump 320A along the first direction D1 to the buffer tank 340, while the second pump 320B remains deactivated or in the “OFF” state. This ensures that the filtered portion of resist liquid PR is retained in the buffer tank 340, preventing it from immediately returning to the storage tank 310.

In operation 506, a fraction of the filtered resist liquid is pumped from the second tank back to the first tank to mix with the unfiltered resist liquid. FIG. 8C illustrates this process, where less than 100% of the filtered resist liquid PR in the buffer tank 340 is pumped back to the storage tank 310 by the second pump 320B. Stated differently, a volume of the resist liquid pumped from the buffer tank 340 back to the storage tank 310 is less than a volume of the resist liquid previously pumped from the storage tank 310 to the buffer tank 340. During this step, the second pump 320B is activated, as indicated by the “ON” label in FIG. 8C, enabling the filtered resist liquid PR to flow through the second pump 320B in the direction D2 towards the storage tank 310, while the first pump 320A remains deactivated or in the “OFF” state.

In some embodiments, the amount of resist liquid PR pumped from the buffer tank 340 back to the storage tank 310 is less than the amount initially transferred from the storage tank 310 to the buffer tank 340. This approach reduces the time for pumping the filtered resist liquid PR back to the storage tank 310, thereby enhancing the efficiency of the resist filtration process.

In some embodiments, the controller 374 initiates operation 506 when it determines that the liquid level in the storage tank 310 has dropped below a predetermined threshold. For example, when the real-time liquid level signals S1 generated by the liquid level monitor 372 indicates that the liquid level in the storage tank 310 has decreased from an initial level L21 to a level L22, which is less than, for example, 30% of the initial level L21, the controller 374 can activate the second pump 320B to pump the filtered resist liquid PR from the buffer tank 340 back to the storage tank 310 in response to the real-time liquid level signals S1.

In some embodiments, the controller 374 halts the operation 506 when it determines that the liquid level in the storage tank 310 has risen to above a predetermined threshold. For example, when the real-time liquid level signals S1 generated by the liquid level monitor 372 indicates that the liquid level in the storage tank 310 has increased from a previous level L22 to a level L25, which is more than, for example, 50% of the previous level L22 but still less than the initial level L21 in the storage tank 310, the controller 374 can deactivate the second pump 320B to stop pumping the filtered resist liquid PR from the buffer tank 340 back to the storage tank 310 in response to the real-time liquid level signals S1. This ensures that the amount of resist liquid PR pumped from the buffer tank 340 back to the storage tank 310 is less than the amount initially transferred from the storage tank 310 to the buffer tank 340, thereby enhancing the efficiency of the resist filtration process, because the operation 506 can take less duration than operation 504.

In some other embodiments, the controller 374 halts the operation 506 when it determines that the liquid level in the buffer tank 340 has dropped below a predetermined threshold. For example, when the real-time liquid level signals S4 generated by the liquid level monitor 376 indicates that the liquid level in the buffer tank 340 has decreased from a previous level L23 to a level L24, which is less than, for example, 50% of the previous level L23, the controller 374 can deactivate the second pump 320B. This action stops the pumping of the filtered resist liquid PR from the buffer tank 340 back to the storage tank 310 in response to the real-time liquid level signals S4. This ensures that the amount of resist liquid PR pumped from the buffer tank 340 back to the storage tank 310 is less than the amount initially transferred from the storage tank 310 to the buffer tank 340, thereby enhancing the efficiency of the resist filtration process, because the operation 506 can take less duration than operation 504.

In operation 508, the mixed resist liquid in the storage tank 310 is inspected to obtain a defect count in the mixed liquid. If the defect count is determined as unacceptable, then the resist filtration process 500 returns to perform the operations 504 and 506. The operations 504, 506, and 508 thus collectively form a cyclic process C2 that may repeat until in the latest operation 508 the defect count in the mixed resist liquid is acceptable, i.e., lower than a predetermined threshold. Once the defect count is determined as acceptable, in operation 510, the mixed resist liquid is transferred to a resist container. For example, when the defect count in the mixed resist liquid in the storage tank 310 is determined as acceptable, the controller 374 may switch the open/closed positions of outlet ports in the valve 360, enabling the mixed resist liquid exits the circulation loop to the resist container 202 through the outlet pipeline 304.

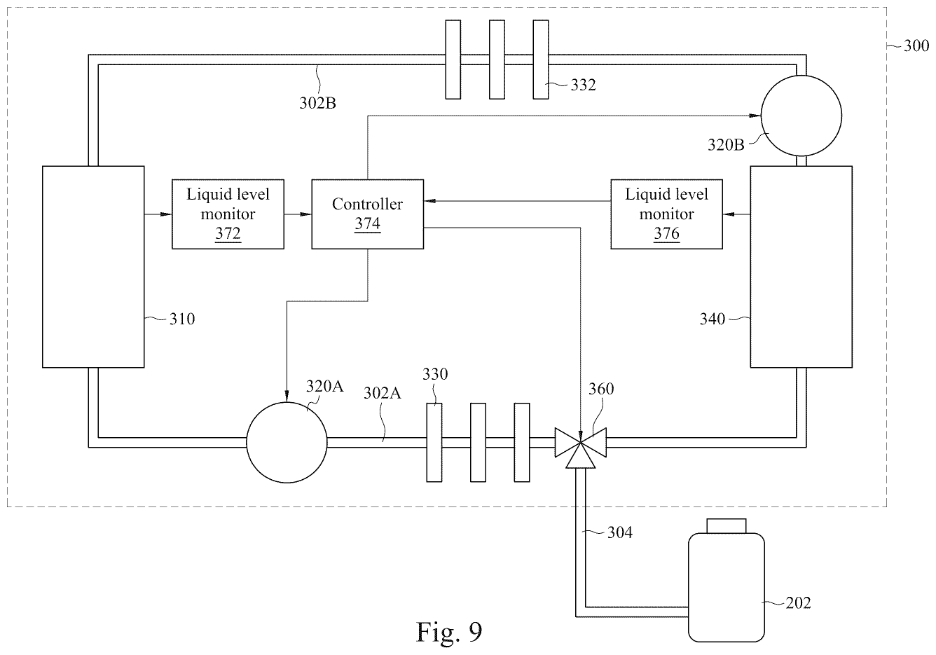

FIG. 9 illustrates a diagram of a resist filtration system 300a in accordance with some embodiments of the present disclosure. The resist filtration system 300a is substantially the same as the resist filtration 300 illustrated in FIG. 3, except that the resist filtration system 300a further includes one or more filters 332 in the second pipeline 302B downstream of the buffer tank 340 and upstream of the storage tank 310. When the second pump 320B initiates and drives a flow of resist liquid through the second pipeline 302B, the filters 332 can remove defects such as particles, thereby further reducing the defect concentration in the filtered resist liquid.

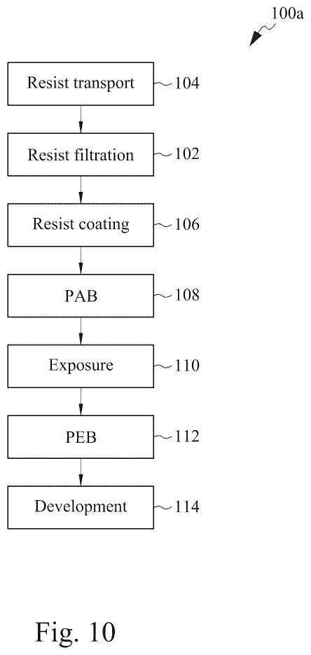

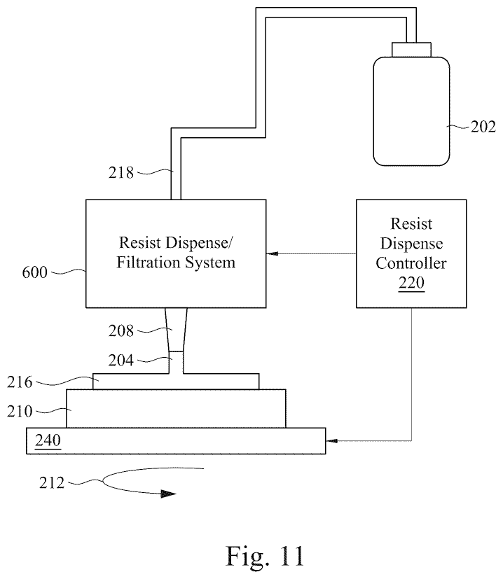

FIG. 10 is a flow chart illustrating another exemplary process 100a for generating a layout pattern in a resist layer on a wafer, in accordance with some embodiments of the present disclosure. The process 100a is substantially the same as the process 100 discussed with respect to FIG. 1, except that in the process 100a the multi-tank resist filtration process is performed in-line in the lithography tool in the FAB, not in a stand-alone facility operated by the photoresist vendor. Process 100a begins from operation 104, where a resist liquid is transported to a lithography tool in a FAB, as illustrated in FIG. 11. Then, in operation 102, the resist liquid is filtered in a resist dispense/filtration system 600 in the lithography tool in a semiconductor fabrication facility (FAB), as illustrated in FIG. 11. After the resist filtration operation 102 is completed, the process 100a proceeds to operation 106, where the filtered resist liquid is dispensed, e.g., coated, on a top surface of a substrate, e.g., a wafer or a work piece, to form a resist layer. Other operations, such as PAB operation 108, exposure operation 110, PEB operation 112, and development operation 114 are the same as that discussed previously with respect to FIG. 1, and thus are not repeated for the sake of brevity.

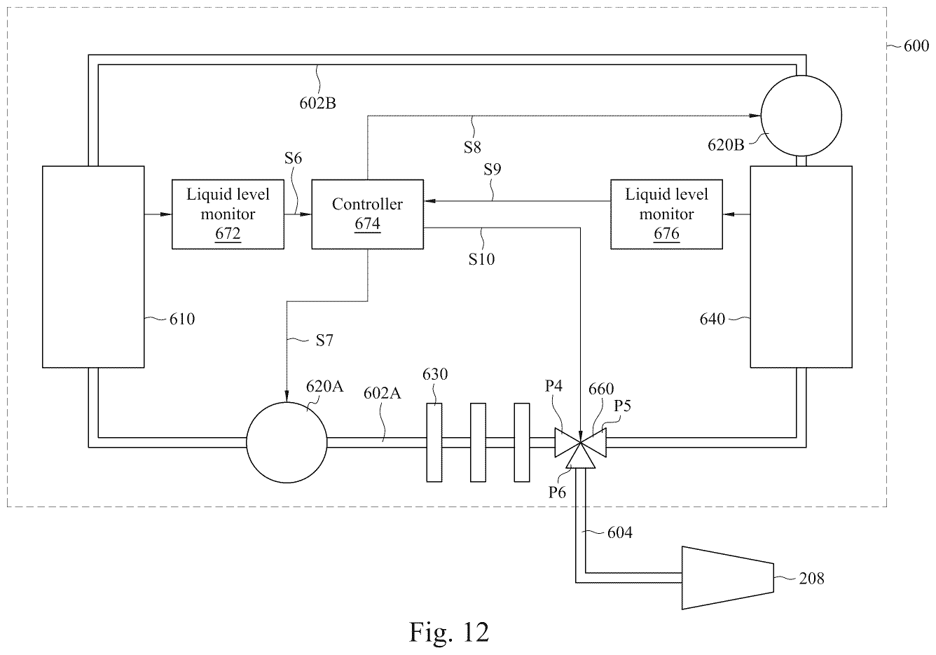

FIG. 12 illustrates a diagram of a resist dispense/filtration system 600 in accordance with some embodiments of the present disclosure. The resist dispense/filtration system 600 includes a circulation loop comprising a storage tank 610, one or more filters 630 downstream of the storage tank 610, one or more buffer tanks 640 downstream of the one or more filters 630, a first pipeline 602A downstream of the storage tank 610 and upstream of the buffer tank 640 and fluidly connecting the storage tank 610 to the buffer tank 640, a second pipeline 602B downstream of the buffer tank 640 and upstream of the storage tank 610 and fluidly connecting the buffer tank 640 to the storage tank 610, a first pump 620A fluidly connected to the first pipeline 602A, and a second pump 620B fluid connected to the second pipeline 602B.

The first pump 620A can initiate and drive a flow of resist liquid through the first pipeline 602A, enabling the resist liquid to flow from the storage tank 610 to the buffer tank 640 via one or more filters 630. The second pump 620B can initiate and drive a flow of resist liquid through the second pipeline 602B, enabling the resist liquid to return from the buffer tank 640 back to the storage tank 610. Together, the first pipeline 602A and the second pipeline 602B enable the circulation of the resist liquid within the loop.

As the unfiltered resist liquid flows through one or more filters 630 in the first pipeline 602A, the filters 630 remove defects such as particles, thereby reducing the defect concentration in the resist liquid. Once filtered, the filtered resist liquid flows into the buffer tank 640, where it can be temporarily stored instead of immediately returning to the storage tank 610. For instance, when the first pump 620A is activated (i.e., turned on), it drives the resist liquid to flow through the filters 630 and into the buffer tank 640. During this time, the second pump 620B remains deactivated (i.e., turned off), allowing the filtered resist liquid to remain stationary in the buffer tank 640. Once the first pump 620A has sufficiently lowered the liquid level in the storage tank 610 below a predetermined threshold (e.g., 30% of its initial liquid level), the second pump 620B is activated. This activation initiates the flow of filtered resist liquid from the buffer tank 640 back to the storage tank 610, where it mixes with the unfiltered resist liquid.

In some embodiments, the resist filtration system 600 includes a liquid level monitor 672 that is either connected to or integrated within the storage tank 610, and a liquid level monitor 676 that is either connected to or integrated within the buffer tank 640. This liquid level monitor 672 continuously tracks the liquid level in the storage tank 610 during the filtration process, generating real-time liquid level signals S6 based on the monitored data. These real-time signals S6 are then transmitted to a controller 674, which is in communication with the liquid level monitor 672. Similarly, the liquid level monitor 676 continuously tracks the liquid level in the buffer tank 640 during the filtration process, generating real-time liquid level signals S9 based on the monitored data. These real-time signals S9 are then transmitted to the controller 674, which is also in communication with the liquid level monitor 676. The controller 674 processes the real-time liquid level signals S6 and/or S9, and generates corresponding control signals S7 and S8, such as control voltages, based on the real-time liquid level signals S6 and/or S9. These control signals S7 and S8 are used to manage the operation of the pumps 620A and 620B. For example, the control signals S7 are sent to the first pump 620A to regulate its activation or deactivation, and the control signals S9 are sent to the second pump 620B to regulate its activation or deactivation.

In some embodiments, each of the liquid level monitors 672 and 676 may include a capacitive level sensor, an ultrasonic level sensor, optical sensor, pressure transducer, or a float switch, among other types of liquid level sensors. In some embodiments, the controller 674 may include various types of controllers, such as, for example, a programmable logic controller (PLC), a microcontroller, a digital signal processor (DSP), or the like.

In some embodiments, the resist filtration system 600 further includes a valve 660 that regulates whether the resist liquid remains within the circulation loop or exits the loop through an outlet pipeline 604 for the next stage, such as being dispensed onto a wafer through a resist dispensing nozzle 208. In some embodiments, the valve 660 is a three-way valve, which offers enhanced control over the flow direction of the resist liquid. For example, the three-way valve 660 operates by providing three ports, which include an inlet port P4 and two outlet ports P5 and P6. The inlet port P4 of the three-way valve 660 receives the resist liquid from the last one of filters 630 in the circulation loop. The first outlet port P5 of the three-way valve 660 directs the resist liquid back into the circulation loop to the buffer tank 640. The second outlet port P6 of the three-way valve 660 allows the resist liquid to exit the circulation loop through the outlet pipeline 604 to the next stage, such as directly being dispensed onto a wafer through the resist dispensing nozzle 208.

In some embodiments, the controller 674 can manage the operation of the three-way valve 660 by sending control signals S10, such as control voltages, to switch the open/closed position of each port of the three-way valve 660. When the controller 674 determines that the resist liquid remains in the circulation loop for continuing the filtration process, the control signal S10 controls the three-way valve 660 to maintain an open position on the first outlet port P5 and a closed position on the second outlet port P6, thereby regulating the resist liquid to stay in the circulation loop. Conversely, when the controller 674 determines that the filtration process is completed and the resist liquid can be moved to the next stage, the controller 674 sends a control signal S10 to switch the three-way valve 660 to have a closed position on the first outlet port P5 and an open position on the second outlet port P6, allowing the resist liquid to flow out of the circulation loop and to be dispensed onto a wafer through the resist dispensing nozzle 208.

In some embodiments, the first pump 620A and the second pump 620B operate asynchronously. For example, the first pump 620A and the second pump 620B are asynchronously activated by the controller 674. Specifically, the controller 674 activates the second pump 620B after the first pump 620A has been running for a sufficient duration. This allows that the filtered resist liquid remains in the buffer tank 640 until the first pump 620A has lowered the liquid level in the storage tank 610 below a predetermined threshold, such as 30% of its initial level. In some embodiments, the first pump 620A and the second pump 620B are asynchronously deactivated by the controller 674. For example, the controller 674 may activate and deactivate the second pump 620B after deactivating the first pump 620A. This prevents mixed resist liquid from being transferred from the storage tank 610 to the buffer tank 640 while the filtered resist liquid is being pumped back from the buffer tank 640 to the storage tank 610.

In some embodiments, one or more filters 630 are formed from materials such as nylon, high-density polyethylene (HDPE), perfluoroalkoxy alkane (PFA), or other types of polymers and materials that can be effectively used in photoresist particle filtration. In some embodiments, the storage tank 610 and/or the buffer tank 640 for the resist filtration are formed from materials such as PFA (perfluoroalkoxy alkane), PTFE (polytetrafluoroethylene), HDPE (high-density polyethylene), or glass.

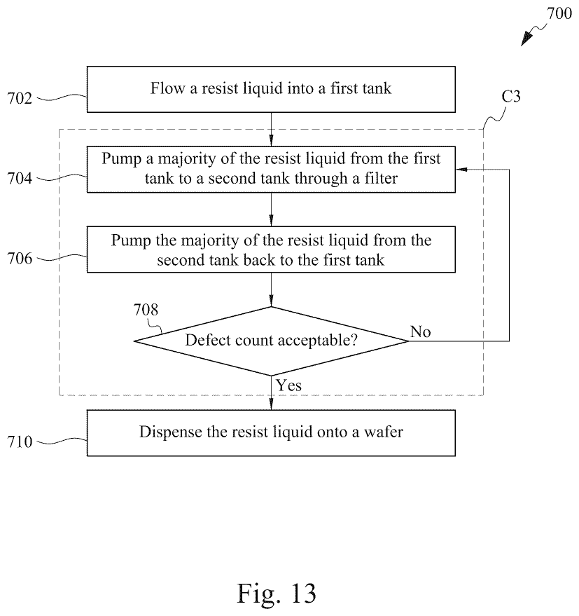

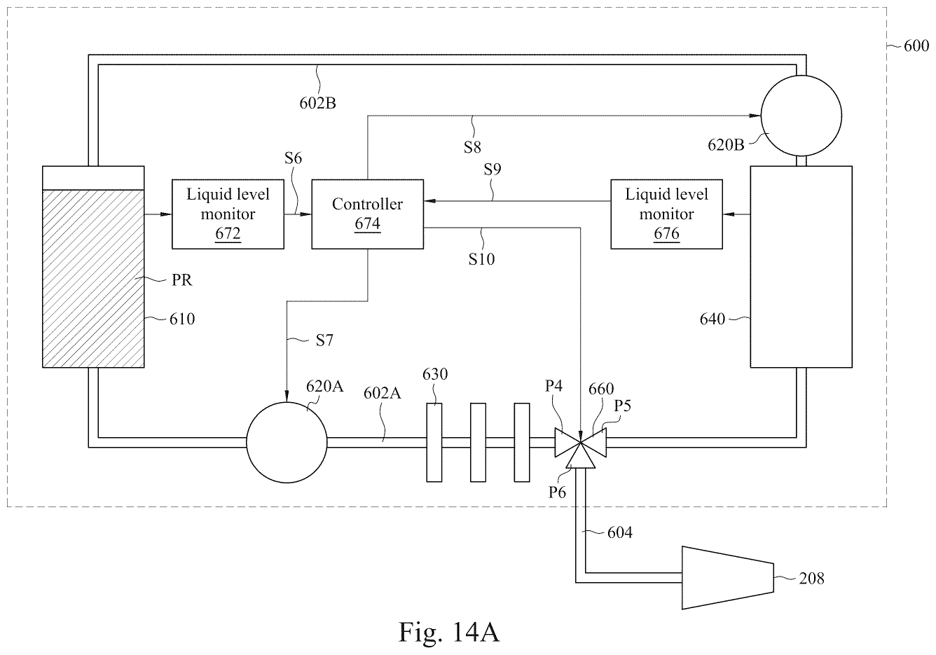

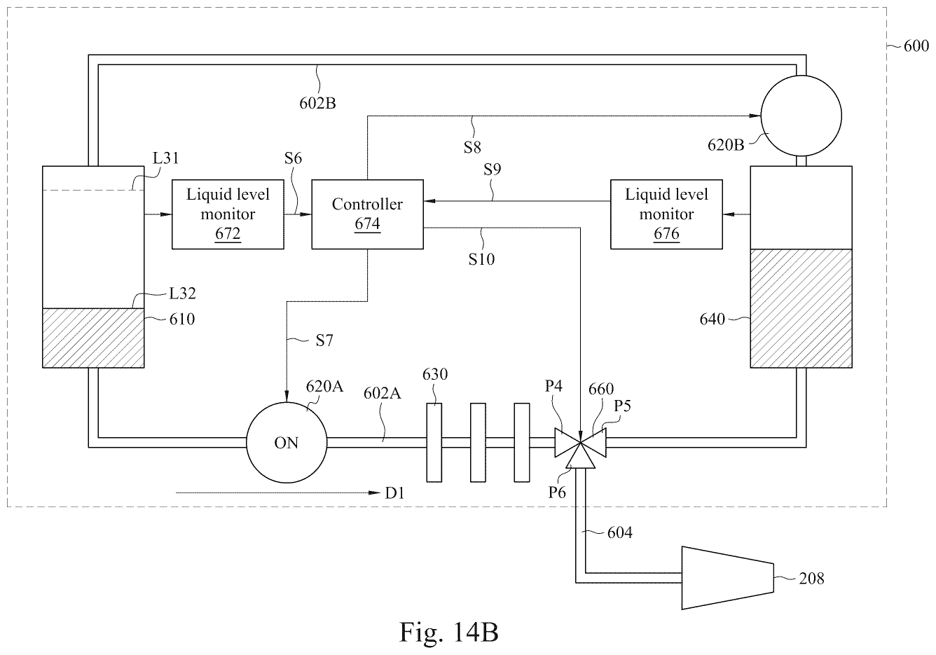

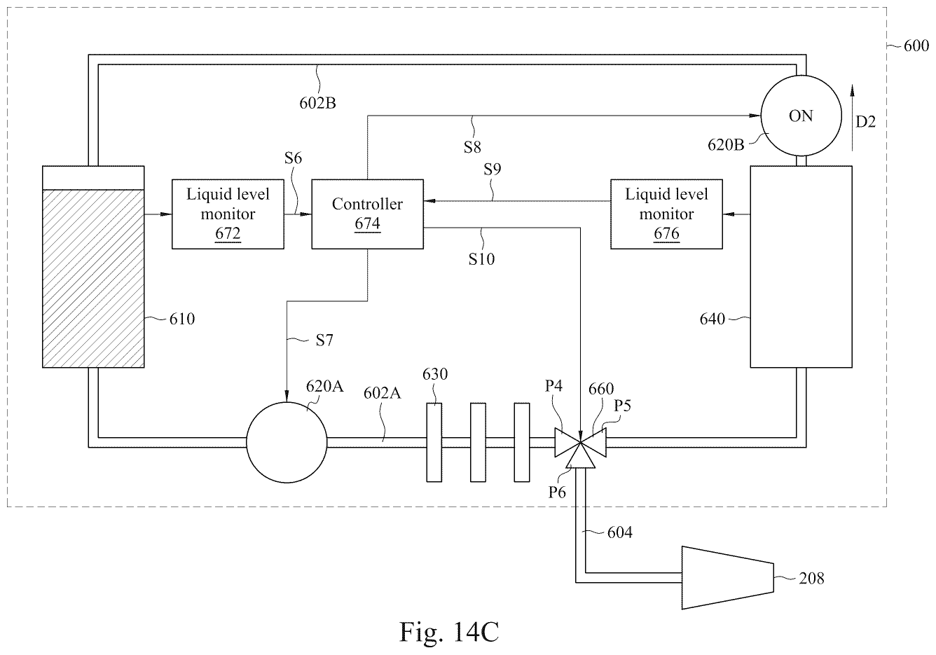

FIG. 13 is a flow chart illustrating an exemplary resist filtration process 700 in accordance with some embodiments of the present disclosure. In operation 702, a resist liquid flows into a first tank. FIG. 14A illustrates an example of operation 402, where a resist liquid PR, e.g., photoresist, flows into the storage tank 610 of the resist dispense/filtration system 600 through a pipeline 218 fluidly connected to a resist container 202, such as a resist bottle received from a resist vendor.

In operation 704, a majority of the resist liquid is pumped from the first tank to a second tank through a filter. FIG. 14B illustrates an example of operation 704, where a majority of the resist liquid PR (e.g., more than 70% of the resist liquid PR) is pumped from the storage tank 610 to the buffer tank 640 through one or more filters 630 by the first pump 620A. During this step, the first pump 620A is activated, as indicated by the “ON” label in FIG. 14B, enabling the resist liquid PR to flow through the first pump 620A along the first direction D1 to the buffer tank 640, while the second pump 620B remains deactivated or in the “OFF” state. This ensures that the resist liquid PR is retained in the buffer tank 640, preventing it from immediately returning to the storage tank 610.

In operation 706, the majority of the resist liquid is pumped from the second tank back to the first tank to mix with the resist liquid in the first tank. FIG. 14C illustrates an example of operation 706, where an entirety of the filtered resist liquid PR in the buffer tank 640 is pumped from the buffer tank 640 back to the storage tank 610 by the second pump 620B to mix to the unfiltered resist liquid PR in storage tank 610. During this step, the second pump 620B is activated, as indicated by the “ON” label in FIG. 14C, enabling the resist liquid PR to flow through the second pump 620B along the second direction D2 to the storage tank 610, while the second pump 620A may remain deactivated or in the “OFF” state. This ensures that the mixed resist liquid PR is retained in the storage tank 610, preventing it from immediately flowing to the buffer tank 640.

In some embodiments, the operation 706 is initiated by the controller 674 when it determines that the liquid level in the storage tank 610 has dropped below a predetermined threshold. For example, when the real-time liquid level signals S6 generated by the liquid level monitor 672 indicates that the liquid level in the storage tank 610 has decreased from an initial level L31 to a level L32, which is less than, for example, 30% of the initial level L31, the controller 674 can activate the second pump 620B to pump the resist liquid PR from the buffer tank 640 back to the storage tank 610 in response to the real-time liquid level signals S6.

In operation 708, the mixed resist liquid is inspected to obtain a defect count in the mixed liquid. If the defect count is determined as unacceptable, then the resist filtration process 700 returns to perform the operations 704 and 706. The operations 704, 706, and 708 thus collectively form a cyclic process C3 that may repeat until in the latest operation 708 the defect count in the mixed resist liquid is acceptable, i.e., lower than a predetermined threshold. Once the defect count is determined as acceptable, in operation 710, the mixed resist liquid is dispensed onto a wafer. For example, when the defect count in the mixed resist liquid in the storage tank 610 is determined as acceptable, the controller 674 may switch the open/closed positions of outlet ports in the valve 660, enabling the mixed resist liquid in the storage tank 610 to exit the circulation loop to dispense onto a wafer through the outlet pipeline 604 and the resist dispensing nozzle 208 at the end of the outlet pipeline 604.

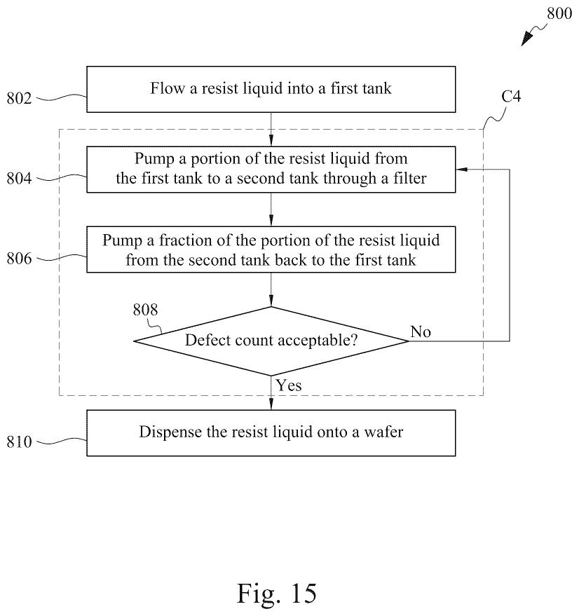

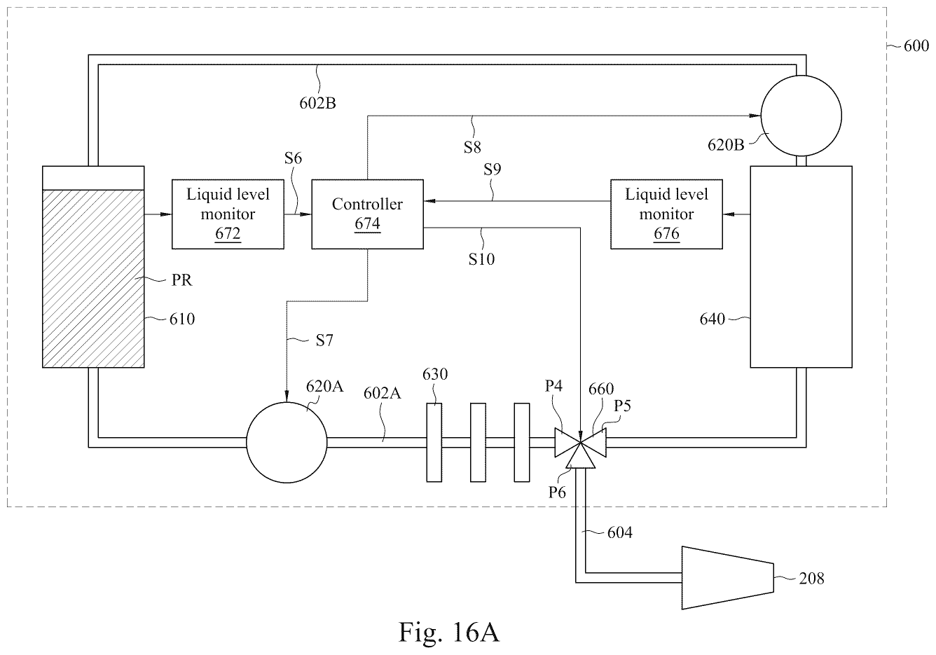

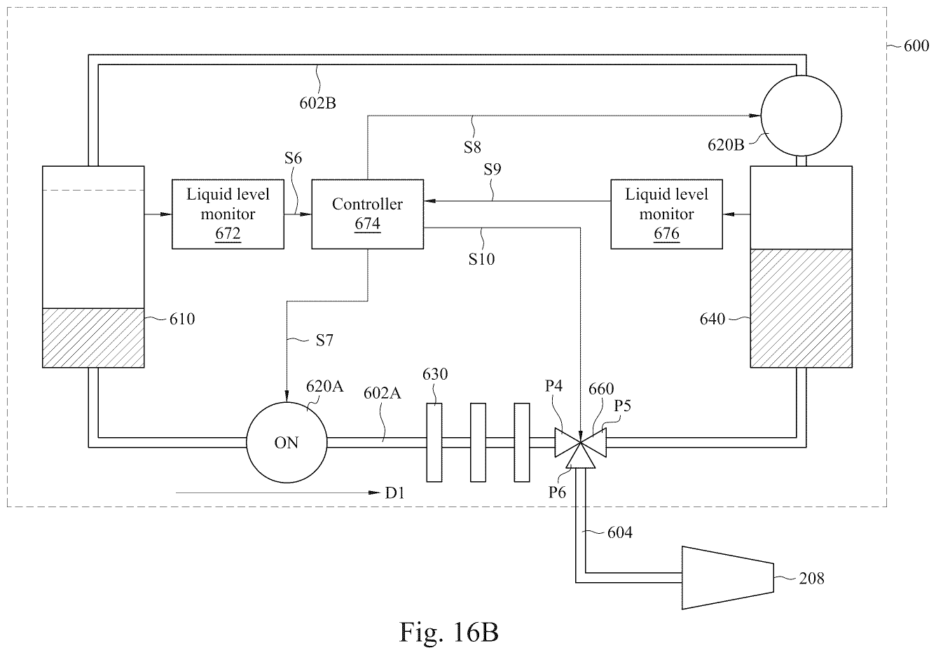

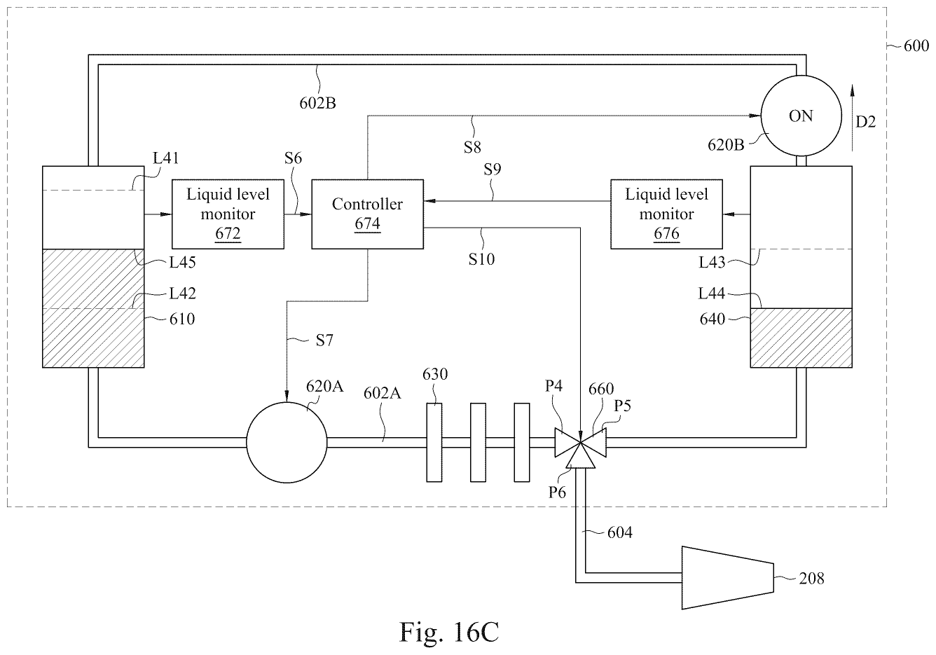

FIG. 15 is a flow chart illustrating another exemplary resist filtration process 800 in accordance with some embodiments of the present disclosure. In operation 802, a resist liquid flows into a first tank. FIG. 16A illustrates an example of operation 802, where a resist liquid PR, e.g., photoresist, flows into the storage tank 610 of the resist dispense/filtration system 600 from a resist container 202 through a pipeline 218.

In operation 804, a portion of the resist liquid is pumped from the first tank to a second tank through a filter. FIG. 16B illustrates an example of operation 804, where a portion of the resist liquid PR (e.g., more than 70% of the resist liquid PR) is pumped from the storage tank 610 to the buffer tank 640 through one or more filters 630 by the first pump 620A. During this step, the first pump 620A is activated, as indicated by the “ON” label in FIG. 16B, enabling the resist liquid PR to flow through the first pump 620A along the first direction D1 to the buffer tank 640, while the second pump 620B remains deactivated or in the “OFF” state. This ensures that the filtered portion of resist liquid PR is retained in the buffer tank 640, preventing it from immediately returning to the storage tank 610.

In operation 806, a fraction of the filtered resist liquid is pumped from the second tank back to the first tank to mix with the unfiltered resist liquid. FIG. 16C illustrates this process, where less than 100% of the filtered resist liquid PR in the buffer tank 640 is pumped back to the storage tank 610 by the second pump 620B. During this step, the second pump 620B is activated, as indicated by the “ON” label in FIG. 16C, enabling the filtered resist liquid PR to flow through the second pump 620B in the direction D2 towards the storage tank 610, while the first pump 620A remains deactivated or in the “OFF” state.

In some embodiments, the amount of resist liquid PR pumped from the buffer tank 640 back to the storage tank 610 is less than the amount initially transferred from the storage tank 610 to the buffer tank 640. This approach reduces the time for pumping the filtered resist liquid PR back to the storage tank 610, thereby enhancing the efficiency of the resist filtration process.

In some embodiments, the controller 674 initiates operation 806 when it determines that the liquid level in the storage tank 610 has dropped below a predetermined threshold. For example, when the real-time liquid level signals S6 generated by the liquid level monitor 672 indicates that the liquid level in the storage tank 610 has decreased from an initial level L41 to a level L42, which is less than, for example, 30% of the initial level L41, the controller 674 can activate the second pump 620B to pump the filtered resist liquid PR from the buffer tank 640 back to the storage tank 610 in response to the real-time liquid level signals S6.

In some embodiments, the controller 674 halts the operation 806 when it determines that the liquid level in the storage tank 610 has risen to above a predetermined threshold. For example, when the real-time liquid level signals S6 generated by the liquid level monitor 672 indicates that the liquid level in the storage tank 610 has increased from a previous level L42 to a level L45, which is more than, for example, 50% of the previous level L42 but still less than the initial level L41 in the storage tank 610, the controller 674 can deactivate the second pump 620B to stop pumping the filtered resist liquid PR from the buffer tank 640 back to the storage tank 610 in response to the real-time liquid level signals S6. This ensures that the amount of resist liquid PR pumped from the buffer tank 640 back to the storage tank 610 is less than the amount initially transferred from the storage tank 610 to the buffer tank 640, thereby enhancing the efficiency of the resist filtration process, because the operation 806 can take less duration than operation 804.

In some other embodiments, the controller 674 halts the operation 806 when it determines that the liquid level in the buffer tank 640 has dropped below a predetermined threshold. For example, when the real-time liquid level signals S9 generated by the liquid level monitor 676 indicates that the liquid level in the buffer tank 640 has decreased from a previous level L43 to a level L44, which is less than, for example, 50% of the previous level L43, the controller 674 can deactivate the second pump 620B. This action stops the pumping of the filtered resist liquid PR from the buffer tank 640 back to the storage tank 610 in response to the real-time liquid level signals S9. This ensures that the amount of resist liquid PR pumped from the buffer tank 640 back to the storage tank 610 is less than the amount initially transferred from the storage tank 610 to the buffer tank 640, thereby enhancing the efficiency of the resist filtration process, because the operation 806 can take less duration than operation 804.

In operation 808, the mixed resist liquid in the storage tank 610 is inspected to obtain a defect count in the mixed liquid. If the defect count is determined as unacceptable, then the resist filtration process 800 returns to perform the operations 804 and 806. The operations 804, 806, and 808 thus collectively form a cyclic process C4 that may repeat until in the latest operation 808 the defect count in the mixed resist liquid is acceptable, i.e., lower than a predetermined threshold. Once the defect count is determined as acceptable, in operation 810, the mixed resist liquid is dispensed onto a wafer. For example, when the defect count in the mixed resist liquid in the storage tank 610 is determined as acceptable, the controller 674 may switch the open/closed positions of outlet ports in the valve 660, enabling the mixed resist liquid in the storage tank 610 to exit the circulation loop to dispense onto a wafer through the outlet pipeline 604 and the resist dispensing nozzle 208 at the end of the outlet pipeline 604.

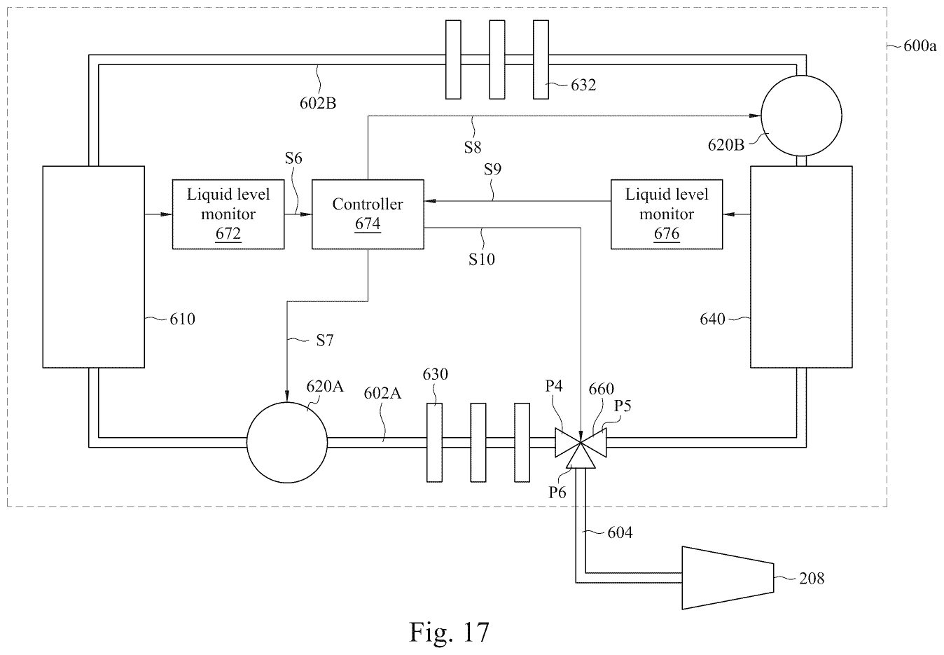

FIG. 17 illustrates a diagram of a resist filtration system 600a in accordance with some embodiments of the present disclosure. The resist filtration system 600a is substantially the same as the resist filtration 600 illustrated in FIG. 12, except that the resist filtration system 600a further includes one or more filters 632 in the second pipeline 602B downstream of the buffer tank 640 and upstream of the storage tank 610. When the second pump 620B initiates and drives a flow of resist liquid through the second pipeline 602B, the filters 632 can remove defects such as particles, thereby further reducing the defect concentration in the filtered resist liquid.

Based on the above discussions, it can be seen that the present disclosure in various embodiments offers advantages. It is understood, however, that other embodiments may offer additional advantages, and not all advantages are necessarily disclosed herein, and that no particular advantage is required for all embodiments. One advantage is that the efficiency of resist filtration process can be improved by using the multi-tank filtration system.

In some embodiments, a method comprises following steps. A resist liquid is flowed into a first tank and a filtration process is performed to the resist liquid. The filtration process comprises one or more repetitions of a cyclic process. The cyclic process comprises following steps: pumping the resist liquid from the first tank to a second tank through a first filter in a first pipeline; determining whether a liquid level in the first tank drops below a first predetermined threshold; and in response to determining that the liquid level in the first tank drops below the first predetermined threshold, pumping the resist liquid from the second tank back to the first tank. In some embodiments, a volume of the resist liquid pumped from the second tank back to the first tank is less than a volume of the resist liquid pumped from the first tank to the second tank. In some embodiments, a volume of the resist liquid pumped from the second tank back to the first tank is substantially equal to a volume of the resist liquid pumped from the first tank to the second tank. In some embodiments, the cyclic process further comprises in response to determining that the liquid level in the first tank is above the first predetermined threshold, keeping the resist liquid in the second tank without pumped back to the first tank. In some embodiments, the resist liquid is pumped from the second tank back to the first tank through a second pipeline different from the first pipeline. In some embodiments, the second pipeline has a second filter. In some embodiments, the cyclic process further comprises monitoring the liquid level in the first tank by using a liquid level monitor. In some embodiments, the cyclic process further comprises during pumping the resist liquid from the second tank back to the first tank, determining whether a liquid level in the second tank drops below a second predetermined threshold; and in response to determining that the liquid level in the second tank drops below the second predetermined threshold, stopping pumping the resist liquid from the second tank back to the first tank. In some embodiments, the cyclic process further comprises during pumping the resist liquid from the second tank back to the first tank, determining whether the liquid level in the first tank rises above a third predetermined threshold; and in response to determining that the liquid level in the first tank rises above the third predetermined threshold, stopping pumping the resist liquid from the second tank back to the first tank. In some embodiments, the method further comprises after performing the filtration process, transferring the resist liquid into a resist container. In some embodiments, the method further comprises after performing the filtration process, dispensing the resist liquid onto a wafer.

In some embodiments, a method comprises the following steps. A resist liquid is introduced into a first tank in a resist filtration system. The resist filtration system includes a filter-containing pipeline connecting the first tank to a second tank. The resist liquid is flowed from the first tank to the second tank through a filter-containing pipeline. When a filtered portion of the resist liquid reaches the second tank, the filtered portion remains in the second tank while another portion of the resist liquid continues to flow from the first tank to the second tank. After a liquid level in the first tank drops below a predetermined threshold. The filtered portion of the resist liquid is flowed from the second tank back to the first tank. In some embodiments, flowing the resist liquid from the first tank to the second tank through the filter-containing pipeline comprises activating a first pump fluidly connected to the filter-containing pipeline. In some embodiments, flowing the filtered portion of the resist liquid from the second tank back to the first tank comprises activating a second pump fluidly connected to a pipeline connecting the second tank to the first tank. In some embodiments, the second pump keeps deactivated during flowing the resist liquid from the first tank to the second tank through the filter-containing pipeline. In some embodiments, the pipeline connecting the second tank to the first tank is a filter-containing pipeline. In some embodiments, the pipeline connecting the second tank to the first tank is a filter-free pipeline.

In some embodiments, a resist filtration system comprises a first tank, at least one second tank, a first pipeline downstream of the first tank and upstream of the second tank, a second pipeline downstream of the second tank and upstream of the first tank, one or more first filters in the first pipeline, a first pump in fluid communication with the first pipeline to allow a resist liquid flow from the first tank to the second tank, a second pump in fluid communication with the second pipeline to allow a resist liquid flow from the second tank to the first tank, and a controller. The controller is operable to asynchronously activate the first pump and the second pump. The asynchronous activation comprises activating the first pump while remains the second pump deactivated, and activating the second pump after a liquid level in the first tank drops below a predetermined threshold.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
flowing a resist liquid into a first tank; and
performing a filtration process to the resist liquid, the filtration process comprising one or more repetitions of a cyclic process, the cyclic process comprising:
pumping the resist liquid from the first tank to a second tank through a first filter in a first pipeline;
determining whether a liquid level in the first tank drops below a first predetermined threshold; and
in response to determining that the liquid level in the first tank drops below the first predetermined threshold, pumping the resist liquid from the second tank back to the first tank.

2. The method of claim 1, wherein a volume of the resist liquid pumped from the second tank back to the first tank is less than a volume of the resist liquid pumped from the first tank to the second tank.

3. The method of claim 1, wherein a volume of the resist liquid pumped from the second tank back to the first tank is substantially equal to a volume of the resist liquid pumped from the first tank to the second tank.

4. The method of claim 1, wherein the cyclic process further comprises:
in response to determining that the liquid level in the first tank is above the first predetermined threshold, keeping the resist liquid in the second tank without pumped back to the first tank.

5. The method of claim 1, wherein the resist liquid is pumped from the second tank back to the first tank through a second pipeline different from the first pipeline.

6. The method of claim 5, wherein the second pipeline has a second filter.

7. The method of claim 1, wherein the cyclic process further comprises monitoring the liquid level in the first tank by using a liquid level monitor.

8. The method of claim 1, wherein the cyclic process further comprises:
during pumping the resist liquid from the second tank back to the first tank, determining whether a liquid level in the second tank drops below a second predetermined threshold; and
in response to determining that the liquid level in the second tank drops below the second predetermined threshold, stopping pumping the resist liquid from the second tank back to the first tank.

9. The method of claim 1, wherein the cyclic process further comprises:
during pumping the resist liquid from the second tank back to the first tank, determining whether the liquid level in the first tank rises above a third predetermined threshold; and
in response to determining that the liquid level in the first tank rises above the third predetermined threshold, stopping pumping the resist liquid from the second tank back to the first tank.

10. The method of claim 1, further comprising:
after performing the filtration process, transferring the resist liquid into a resist container.

11. The method of claim 1, further comprising:
after performing the filtration process, dispensing the resist liquid onto a wafer.

12. A method, comprising:
introducing a resist liquid into a first tank in a resist filtration system, the resist filtration system comprising a filter-containing pipeline connecting the first tank to a second tank;
flowing the resist liquid from the first tank to the second tank through a filter-containing pipeline, wherein when a filtered portion of the resist liquid reaches the second tank, the filtered portion remains in the second tank while another portion of the resist liquid continues to flow from the first tank to the second tank; and
after a liquid level in the first tank drops below a predetermined threshold, flowing the filtered portion of the resist liquid from the second tank back to the first tank.

13. The method of claim 12, wherein flowing the resist liquid from the first tank to the second tank through the filter-containing pipeline comprises activating a first pump fluidly connected to the filter-containing pipeline.

14. The method of claim 13, wherein flowing the filtered portion of the resist liquid from the second tank back to the first tank comprises activating a second pump fluidly connected to a pipeline connecting the second tank to the first tank.

15. The method of claim 14, wherein the second pump keeps deactivated during flowing the resist liquid from the first tank to the second tank through the filter-containing pipeline.

16. The method of claim 14, wherein the pipeline connecting the second tank to the first tank is a filter-containing pipeline.

17. The method of claim 14, wherein the pipeline connecting the second tank to the first tank is a filter-free pipeline.

18. A resist filtration system, comprising:
a first tank;
at least one second tank;
a first pipeline downstream of the first tank and upstream of the second tank;
a second pipeline downstream of the second tank and upstream of the first tank;
one or more first filters in the first pipeline;
a first pump in fluid communication with the first pipeline to allow a resist liquid flow from the first tank to the second tank;
a second pump in fluid communication with the second pipeline to allow a resist liquid flow from the second tank to the first tank; and
a controller operable to asynchronously activate the first pump and the second pump, wherein the asynchronous activation comprises activating the first pump while remains the second pump deactivated, and activating the second pump after a liquid level in the first tank drops below a predetermined threshold.

19. The resist filtration system of claim 18, further comprising:
one or more second filters in the second pipeline.

20. The resist filtration system of claim 18, further comprising:
a valve in the first pipeline, the valve comprising an inlet port downstream of the one or more first filters, a first outlet port upstream of the second tank, and a second outlet port upstream of a dispensing nozzle.
